(19) United States
(12) Patent Application Publication
(10) Pub. No.: US 2025/0185432 A1
(43) Pub. Date: Jun. 5, 2025

(54) METHOD OF MANUFACTURING PHOTOELECTRONIC DEVICE WITH MULTIPLE WAVELENGTHS AND PHOTOELECTRONIC DEVICE

(71) Applicant: Korean Advanced Nano Fab Center, Suwon-si (KR)

(72) Inventors: Hyeong Ho PARK, Daejeon (KR); Eun Jeong Youn, Suwon-si (KR); Sang Hyun Jung, Suwon-si (KR)

(73) Assignee: KOREAN ADVANCED NANO FAB CENTER, Suwon-si (KR)

(21) Appl. No.: 18/938,662

(22) Filed: Nov. 6, 2024

(30) Foreign Application Priority Data
Dec. 5, 2023 (KR) 10-2023-0174089

(51) Int. Cl. H01L 27/15; H01L 33/00; H01L 33/12; H01L 33/24; H01L 33/30; H01L 33/32; H01L 33/36; H01L 33/44

(52) U.S. Cl. CPC H10H 29/10; H10H 20/013; H10H 20/0133; H10H 20/01335; H10H 20/0137; H10H 20/815; H10H 20/821; H10H 20/824; H10H 20/825; H10H 20/83; H10H 20/84; H10H 20/032; H10H 20/034

(57) ABSTRACT

Disclosed is a method of manufacturing a photoelectronic device having multiple wavelengths, the method including forming a plurality of photo-device layers having different emission wavelengths on a substrate, each photo-device layer including a first type semiconductor layer, an active layer, and a second type semiconductor layer from the substrate, forming a buffer layer between the photo-device layers, exposing the second type semiconductor layer to top of each photo-device layer, and opening the first type semiconductor layer on the bottom of each photo-device layer to form a plurality of photo-device portions having different emission wavelengths in a horizontal direction based on the substrate, forming a first electrode in one region on the opened first type semiconductor layer, and forming a second electrode on each photo-device portion.

### CROSS-REFERENCE TO PRIOR APPLICATIONS

This application claims priority to Korean Patent Application No. 10-2023-0174089 filed Dec. 5, 2023, which is all hereby incorporated by reference in their entirety.

### BACKGROUND OF THE INVENTION

### Field of the Invention

The present disclosure relates to a method of manufacturing a photoelectronic device having multiple wavelengths that is imparted with excellent electrical characteristics by forming photo-device portions arranged horizontally using semiconductor layers having multiple wavelengths and a photoelectronic device manufactured by the method.

Three national projects supported by Korean government associated with this invention are described below.
Project Unique Number: 1415185847
Project Serial Number: 20017391
Government Department: MOTIE (Ministry of Trade, Industry and Energy)
Specialized Institution for Project Management: KEIT (Korea Planning & Evaluation of Industrial Technology)
Title of Research Business: Materials/Parts Package Type
Title of Project: “Development of light source manufacturing technology for micro LED RGB pixels of 360 ppi class stacked structure of 1 inch or more”
Contribution Rate: 1/3
Supervising Institute: Point Engineering Co., Ltd.
Research Period: Jan. 1, 2024˜Dec. 31, 2024
Project Unique Number: 2410000401
Project Serial Number: RS-2023-00257784
Government Department: MOTIE (Ministry of Trade, Industry and Energy)
Specialized Institution for Project Management: KEIT (Korea Planning & Evaluation of Industrial Technology)
Title of Research Business: High performance business of nanoinfrastructure process service
Title of Project: “Development of Process Technology for Nanomaterials and Components in Semiconductor and Display”
Contribution Rate: 1/3
Supervising Institute: Korea Electronics Technology Institute
Research Period: Jan. 1, 2024˜Dec. 31, 2024
Project Unique Number: 2410000708
Project Serial Number: RS-2024-00417436
Government Department: MOTIE (Ministry of Trade, Industry and Energy)
Specialized Institution for Project Management: KEIT (Korea Planning & Evaluation of Industrial Technology)
Title of Research Business: The 1st Electronic Component Industrial Technology Development in 2024
Title of Project: “Development of flip-structured microLED chip technology with an external quantum efficiency of more than 50% and a chip size of less than 800 um²”
Contribution Rate: 1/3
Supervising Institute: WaveLord Inc.
Research Period: Apr. 1, 2024˜Dec. 31, 2024

### Description of the Related Art

In accordance with the trend toward high integration and high performance of electric and electronic devices, various attempts are being made to manufacture micro-photoelectronic devices such as micro-light emitting diodes and nano-light emitting diodes.

Recent improvement in high-quality thin film growth technology and device process technology has brought about manufacturing of photoelectronic devices with various sizes. In particular, research is underway on full-color displays using red (R), green (G), and blue (B) micro-light emitting diodes with a size of 100 μm or less.

In conventional methods of realizing full-color displays, RGB pixels are formed using blue micro-light emitting diodes and quantum dots for green- or red-light emission on the blue micro-light emitting diodes. However, commercialization of such methods is limited due to issues such as particle size control of quantum dots, reliability, and limited mass production.

In addition, green and red micro-light-emitting diodes have lower luminous efficacy than blue micro-light-emitting diodes, thus reducing overall efficiency and making it difficult to secure uniformity in color distribution and color reproduction.

In addition, the conventional structure in which red, green, and blue micro-light-emitting diodes are stacked in a vertical direction has problems of color mixing during emission of light from stacked RGB elements, and high driving voltage and leakage current between vertically stacked RGB elements.

In addition, the conventional method requires the areas occupied by each micro-light-emitting diode and the n-electrode and p-electrode for driving each micro-light-emitting diode and thus is not easy to manufacture ultra-small light-emitting diodes required to form large-area, ultra-high-resolution displays, when a full-color pixel is configured based on micro-light-emitting diodes having independent n-electrodes and p-electrodes.

### SUMMARY OF THE INVENTION

Therefore, the present invention has been made in view of the above problems, and it is an object of the present invention to provide a method of manufacturing a photoelectronic device having multiple wavelengths that is imparted with excellent electrical characteristics by forming photo-device portions arranged horizontally using semiconductor layers having multiple wavelengths and a photoelectronic device manufactured by the method.

In accordance with one aspect of the present invention, the above and other objects can be accomplished by the provision of a method of manufacturing a photoelectronic device having multiple wavelengths, the method including forming a plurality of photo-device layers having different emission wavelengths on a substrate, each photo-device layer including a first type semiconductor layer, an active layer, and a second type semiconductor layer from the substrate, forming a buffer layer between the photo-device layers, exposing the second type semiconductor layer to top of each photo-device layer, and opening the first type semiconductor layer on the bottom of each photo-device layer to form a plurality of photo-device portions having different emission wavelengths in a horizontal direction based on the substrate, forming a first electrode in one region on the opened first type semiconductor layer, and forming a second electrode on each photo-device portion.

In accordance with another aspect of the present disclosure, provided is a photoelectronic device having multiple wavelengths, including a plurality of photo-device layers having different emission wavelengths formed on a substrate, each photo-device layer including a first type semiconductor layer, an active layer, and a second type semiconductor layer from the substrate, a buffer layer formed between the photo-device layers, a plurality of photo-device portions having different emission wavelengths formed in a horizontal direction based on the substrate such that the second type semiconductor layer is exposed to a top of each photo-device layer and the first type semiconductor layer is opened on a bottom of each photo-device layer, a first electrode formed in one region on the opened first type semiconductor layer, and a second electrode formed on each photo-device portion.

In addition, the photo-device portions may operate independently from one another.

In addition, the photo-device portions may horizontally share at least one of the first type semiconductor layers and operate independently from or in conjunction with one another.

In addition, an open area of the first type semiconductor layer may have one shape of a polygon, a circle, an ellipse, or a bridge. In addition, the first electrodes formed on the first type semiconductor layers may be arranged on the same horizontal line and may be connected to each other to form a common electrode.

In addition, the method may further include forming a passivation film opening an electrode area over the entire area of the photoelectronic device before or after forming the first electrode and the second electrode. The method may further include connecting the first electrodes formed on the first type semiconductor layer to each other to form a common electrode after forming the passivation film.

In addition, the first electrode and the second electrode may be formed to be flush with each other by adjusting the heights of the first electrode and the second electrode.

In addition, the substrate may include silicon (Si), gallium arsenide (GaAs), gallium phosphide (GaP), gallium arsenide phosphide (GaAsP), boron nitride (BN), SiC, GaN, ZnO, MgO, InP, Ge, InAs, GaSb, sapphire, quartz, or glass.

In addition, the method may further include forming a buffer layer between the substrate and the lowermost first type semiconductor layer. The buffer layer may be a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or may include a plurality of layers including a combination of two or more layers, or may be a single layer containing two or more materials thereof or may include a plurality of layers including a combination of two or more layers.

In addition, the first type semiconductor layer may be an n-type semiconductor layer or a p-type semiconductor layer, and the second type semiconductor layer may be a p-type semiconductor layer or an n-type semiconductor layer.

The n-type semiconductor layer may be a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or may include a plurality of layers including a combination of two or more layers, or may be a single layer containing two or more materials thereof or include a plurality of layers including a combination of two or more layers, and the p-type semiconductor layer may be a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or may include a plurality of layers including a combination of two or more layers, or may be a single layer containing two or more materials thereof or may include a plurality of layers including a combination of two or more layers.

The active layer may be formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb.

In addition, the first type semiconductor layer or the second type semiconductor layer may be any one layer, a plurality of layers or a p/n junction layer of an n⁺⁺-GaN layer, a p⁺⁺-GaN layer, an n⁺⁺-InGaN layer, a p⁺⁺-InGaN layer, an n⁺⁺-AlGaN layer, a p⁺⁺-AlGaN layer, an n⁺⁺-GaAs layer, a p⁺⁺-GaAs layer, an n⁺⁺-InGaAs layer, a p⁺⁺-InGaAs layer, an n⁺⁺-AlGaAs layer, or a p⁺⁺-AlGaAs.

In addition, when the first type semiconductor layer is formed as a p-type semiconductor layer, or when the second type semiconductor layer is formed as a p-type semiconductor layer, a diffusion prevention layer or an electron blocking layer may be formed between each active layer and the p-type semiconductor layer.

In addition, the first electrode may be formed in any one shape of a polygon, a circle, an ellipse, or a bridge. In addition, the first electrodes may be arranged on the same horizontal line and may be connected to each other to form a common electrode.

### BRIEF DESCRIPTION OF THE DRAWINGS

The above and other objects, features, and other advantages of the present disclosure will be more clearly understood from the following detailed description taken in conjunction with the accompanying drawings, in which:

FIGS. 1A, 1B, 1C, 1D, 1E, 1F, 1G, 1H, 1I and 1J are schematic diagrams illustrating a method of manufacturing a photoelectronic device according to an embodiment of the present invention; and

FIGS. 2A, 2B, 2C, 2D, 2E and 2F to 6A, 6B, 6C, 6D, 6E and 6F are schematic diagrams illustrating photoelectronic devices according to various embodiments of the present invention.

### DETAILED DESCRIPTION OF THE INVENTION

The present invention aims at realizing an optimal structure that improves the spatial arrangement efficiency of electrodes and further increases luminous efficacy by designing the shape and structure of photo-device portions and controlling open areas.

In particular, the present invention provides a full-color RGB pixel that exhibits excellent reproducibility over a large area and can be mass-produced by forming a plurality of photo-device layers including a first type semiconductor layer, an active layer, and a second type semiconductor layer in a vertical direction, and forming a plurality of photo-device portions in a horizontal direction on a substrate by selective etching and opening processes.

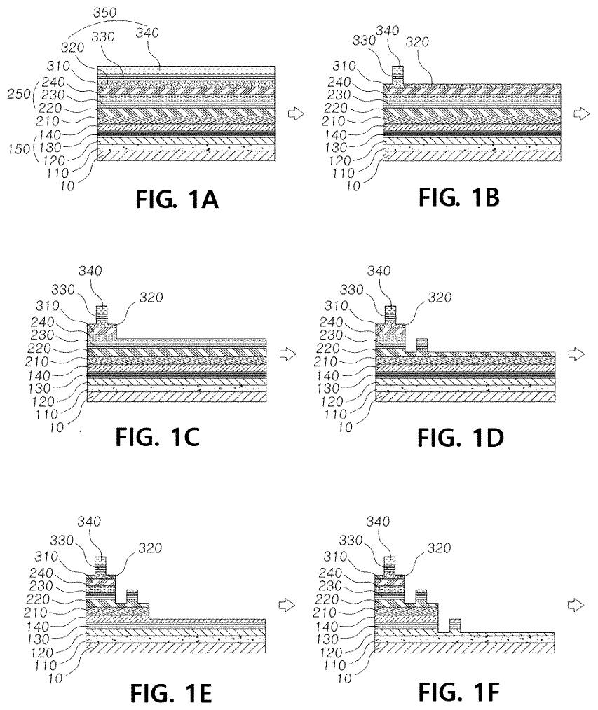

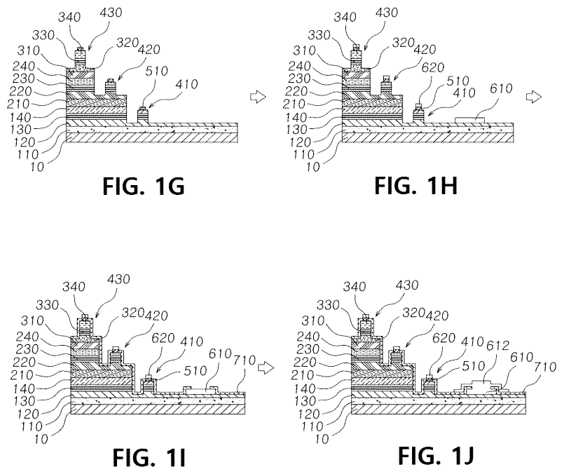

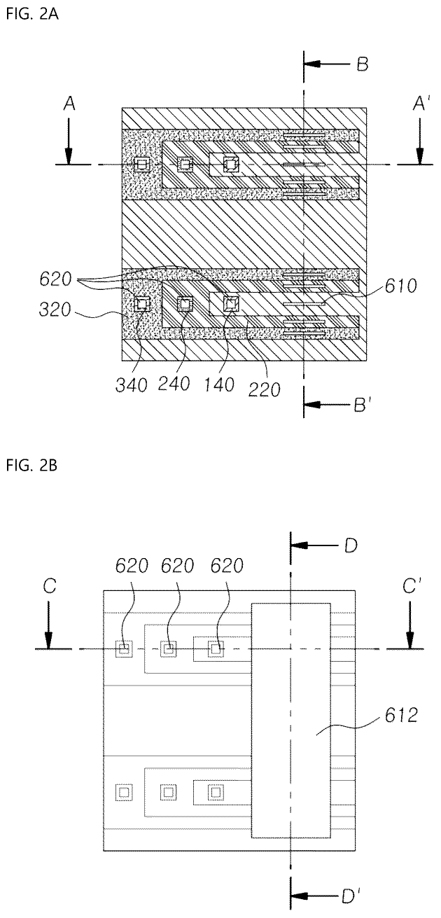

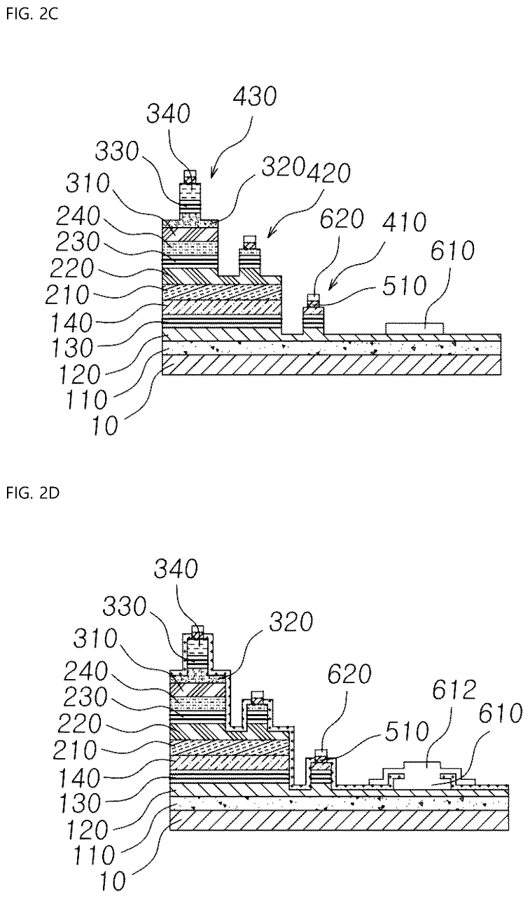

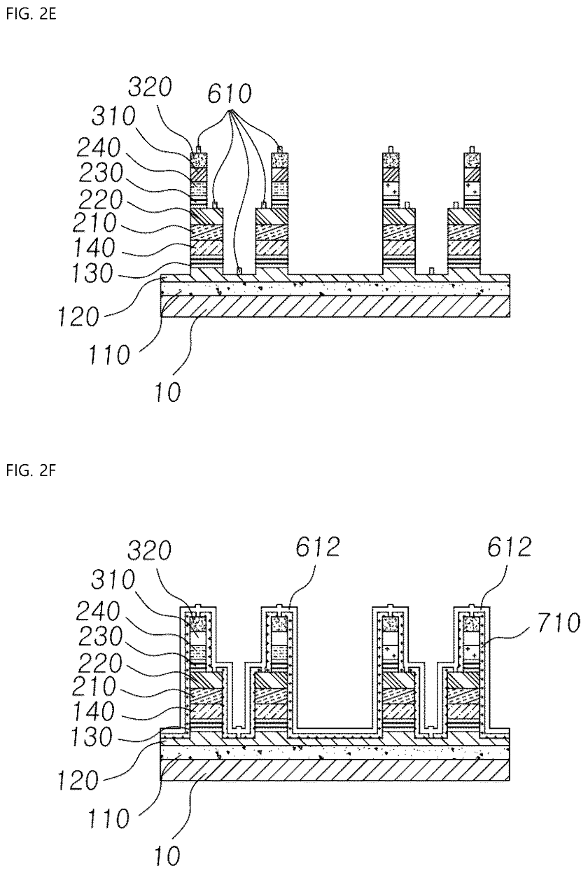

Hereinafter, embodiments of the present invention will be described in detail with reference to the attached drawings. FIGS. 1A, 1B, 1C, 1D, 1E, 1F, 1G, 1H, 1I and 1J are schematic diagrams illustrating a method of manufacturing a photoelectronic device according to an embodiment of the present invention. FIGS. 2A, 2B, 2C, 2D, 2E and 2F to 6A, 6B, 6C, 6D, 6E and 6F are schematic diagrams illustrating photoelectronic devices according to various embodiments of the present invention.

As shown in FIGS. 1A, 1B, 1C, 1D, 1E, 1F, 1G, 1H, 1I and 1J, a method of manufacturing a photoelectronic device having multiple wavelengths according to an embodiment of the present invention includes forming a plurality of photo-device layers 150, 250, and 350 having different emission wavelengths on a substrate 10, wherein each photo-device layer 150, 250, or 350 includes a first type semiconductor layer 120, 220, or 320, an active layer 130, 230, or 130, and a second type semiconductor layer 140, 240, or 340 in this order from the substrate 10, forming buffer layers 210 and 310 between the photo-device layers 150, 250, and 350, exposing the second type semiconductor layers 140, 240, and 340 to the top of the photo-device layers 150, 250, and 350, and opening the first type semiconductor layers 120, 220, and 320 on the bottom of the photo-device layers 150, 250, and 350, to form photo-device portions 410, 420, and 430 having different emission wavelengths in a horizontal direction based on the substrate 10, forming a first electrode 610 in an area on the opened first type semiconductor layers 120, 220, and 320, and forming a second electrode 620 on each photo-device portion 410, 420 and 430.

The photoelectronic device having multiple wavelengths manufactured by the method includes: a plurality of photo-device layers 150, 250, and 350 having different emission wavelengths formed on a substrate 10, wherein each photo-device layer 150, 250, or 350 includes a first type semiconductor layer 120, 220, or 320, an active layer 130, 230, or 130, and a second type semiconductor layer 140, 240, or 340 in this order from the substrate 10; buffer layers 210 and 310 formed between the photo-device layers 150, 250, and 350; photo-device portions 410, 420, and 430 having different emission wavelengths formed in a horizontal direction based on the substrate 10 by exposing the second type semiconductor layers 140, 240, and 340 to the top of the photo-device layers 150, 250, and 350, and opening first type semiconductor layers 120, 220, and 320 on the bottom of the photo-device layers 150, 250, and 350; a first electrode 610 formed in an area on the opened first type semiconductor layers 120, 220, and 320, and a second electrode 620 formed on each photo-device portions 410, 420 and 430.

The light-emitting device according to the present invention may be applied to a light emitting diode (LED), a micro-light emitting diode (micro-LED), a nano-light emitting diode (nano-LED), an ultraviolet light emitting diode (ultraviolet LED), an infrared light emitting diode (infrared LED), a laser diode (LD), a photodiode (PD), an avalanche photodiode (APD), or the like, using III-V, II-VI, and IV-IV compound semiconductors, or semiconductors containing a mixture thereof.

As such, the present invention provides a full-color RGB pixel that exhibits excellent reproducibility over a large area and can be mass-produced by forming a plurality of photo-device layers including a first type semiconductor layer, an active layer, and a second type semiconductor layer in a vertical direction, and forming a plurality of photo-device portions in a horizontal direction on a substrate by selective etching and opening processes.

According to an embodiment of the present invention, first, a plurality of photo-device layers 150, 250, 350, including first type semiconductor layers 120, 220, and 320, active layers 130, 230, and 330, and second type semiconductor layers 140, 240, and 340, respectively, is formed vertically on a substrate 10. Buffer layers 210 and 310 are formed between each of the photo-device layers 150, 250, and 350 to form an epi device layer.

In one embodiment of the present invention, the photoelectronic device includes three photodiode layers 150, 250, and 350, and three buffer layers 110, 210 and 310, wherein the first type semiconductor layer 120, 220, and 320 are n-type semiconductor layers, the second type semiconductor layers 140, 240 and 340 are p-type semiconductor layers, and the second type semiconductor layers 140, 240 and 340 as n-type semiconductor layers are formed to top of the active layers 130, 230 and 330, and the first type semiconductor layers 120, 220 and 320 are formed as n-type semiconductor layers below the active layers 130, 230, and 330 (FIG. 1A).

For example, a buffer layer 110 is formed on a substrate 10, a first photo-device layer 150 including an n-type semiconductor layer, an active layer, and a p-type semiconductor layer is formed, a buffer layer 210 is formed, a second photo-device layer 250 including an n-type semiconductor layer, an active layer, and a p-type semiconductor layer is formed, a buffer layer 310 is formed, and then a third photo-device layer 350 including an n-type semiconductor layer, an active layer, and a p-type semiconductor layer is formed.

Here, the plurality of photo-device layers have different emission wavelengths. Specifically, the first photo-device layer 150 is formed as an active layer having a blue emission wavelength, the second photo-device layer 250 is formed as an active layer having a green emission wavelength, and the third photo-device layer 350 is formed as an active layer having a red emission wavelength.

The substrate 10 according to one embodiment of the present invention includes a substrate used in the process of manufacturing a semiconductor device, or includes a thin film formed on the substrate 10, and may be silicon (Si), gallium arsenide (GaAs), gallium phosphide (GaP), gallium arsenide phosphide (GaAsP), boron nitride (BN), SiC, GaN, ZnO, MgO, InP, Ge, InAs, GaSb, sapphire, quartz, or glass.

As described above, the first type semiconductor layer 120, 220 or 320 may be an n-type semiconductor layer or a p-type semiconductor layer, and the second type semiconductor layer 140, 240, or 340 may be a p-type semiconductor layer or an n-type semiconductor layer.

Here, the n-type semiconductor layer may be a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, and n-AlGaInSb, or include a plurality of layers including a combination of two or more layers, or is a single layer containing two or more materials thereof or include a plurality of layers including a combination of two or more layers.

In addition, the p-type semiconductor layer may be a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or include a plurality of layers including a combination of two or more layers, or may be a single layer containing two or more materials thereof or include a plurality of layers including a combination of two or more layers.

In addition, a buffer layer 110 may be further formed between the substrate 10 and the first type semiconductor layer 120. The buffer layer 110 functions to reduce lattice mismatch between the substrate 10 and the semiconductor layer and may be optionally formed. In addition, a buffer layer 210 or 310 may be formed between the photo-device layers.

According to one embodiment of the present invention, the buffer layers 110, 210, and 310 may be a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or include a plurality of layers including a combination of two or more layers, or may be a single layer containing two or more materials thereof or include a plurality of layers including a combination of two or more layers. The buffer layer 110, 210, or 310 may be a single layer depending on the type of the substrate 10 or the first type semiconductor layer 120, 220, or 320, or may be a stack of a plurality of the materials. The buffer layers 110, 210 and 310 may be formed by a known physical or chemical deposition method.

In addition, the active layers 130, 230 and 330 according to one embodiment of the present invention may be formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb. Based on the combination of these materials, the active layers 130, 230 and 330 may be formed to have the same emission wavelength, or one or a part of the active layers 130, 230, 330 may have a different emission wavelength from the remaining active layers.

According to one embodiment of the present invention, in order to form photo-device portions having red (R), green (G), and blue (B) emission wavelengths, at least three active layers having different emission wavelengths are formed. In general, the band gap can be controlled by controlling the elements with which the material is doped. Generally, for red light emission, a non-nitride material such as GaAs is used, and for green light emission, a GaP-based or a non-nitride material or a nitride material with a controlled doping element such as Al or In may be used.

In one embodiment of the present invention, a buffer layer 110 is formed on a substrate 10, and a first active layer 130 having a blue emission wavelength, a second active layer 230 having a green emission wavelength, and a third active layer 330 having a red emission wavelength are formed in that order on the buffer layer 110. In a device having such a structure, the emission direction is toward the substrate side, and a CMOS backplane, which is a driving substrate of the light-emitting device, is located in the direction opposite to the emission direction.

In addition, according to one embodiment of the present invention, the first type semiconductor layer 120, 220, or 320 or the second type semiconductor layer 140, 240 or 340 is formed as a high-concentration p-type semiconductor layer or a high-concentration n-type semiconductor layer, or as a junction thereof. In one embodiment of the present invention, the doping concentration of each of the first type semiconductor layer 120, 220, or 320, or the second type semiconductor layer 140, 240 or 340 is about 1×10¹⁸ to 1×10²¹ cm⁻³.

According to one embodiment of the present invention, the first type semiconductor layer 120, 220, or 320 or the second type semiconductor layer 140, 240, or 340 may be any one layer, a plurality of layers or a p/n junction layer of an n⁺⁺-GaN layer, a p⁺⁺-GaN layer, an n⁺⁺-InGaN layer, a p⁺⁺-InGaN layer, an n⁺⁺-AlGaN layer, a p⁺⁺-AlGaN layer, an n⁺⁺-GaAs layer, a p⁺⁺-GaAs layer, an n⁺⁺-InGaAs layer, a p⁺⁺-InGaAs layer, an n⁺⁺-AlGaAs layer, or a p⁺⁺-AlGaAs.

In the present invention, the first type semiconductor layers 120, 220, and 320, or the second type semiconductor layers 140, 240, and 340 are formed as high-concentration n-type (n⁺⁺) semiconductor layers and high-concentration p-type (p⁺⁺) semiconductor layers to increase the recombination of electrons and holes in the active layers 130, 230 and 330, and are formed as high-concentration n-type semiconductor layers or p-type semiconductor layers and thus serve as electrode layers of the photo-device portions 410, 420, and 430. Therefore, the shape and structure of the first type semiconductor layers 120, 220, and 320 or the second type semiconductor layers 140, 240, and 340 may be designed in consideration of the arrangement of the electrodes.

In addition, according to one embodiment of the present invention, when the first type semiconductor layers 120, 220, and 320 are formed as p-type semiconductor layers, or the second type semiconductor layers 140, 240, and 340 are formed as p-type semiconductor layers, a diffusion prevention layer or an electron blocking layer is formed between each active layer 130, 230, or 330 and the p-type semiconductor layer to improve the electron-hole combination efficiency. Here, the diffusion prevention layer or the electron blocking layer may be formed using at least one of the p-type semiconductor layer materials.

For example, in one embodiment of the present invention, a buffer layer 110, an n-type semiconductor layer (n⁺⁺-GaN layer), a first active layer (blue light-emitting material) 130, and a p-type semiconductor layer (p⁺⁺-GaN layer) are formed on the substrate 10 to realize a first photo-device layer 150, a buffer layer 210 is formed, and then an n-type semiconductor layer (n⁺⁺-GaN layer), a second active layer (green light-emitting material) 230, and a p-type semiconductor layer (p⁺⁺-GaN layer) are formed to realize a second photo-device layer 250, a buffer layer 310 is formed, and then an n-type semiconductor layer (n⁺⁺-GaN layer), a third active layer (red light-emitting material) 330, and a p-type semiconductor layer (p⁺⁺-GaN layer) are formed to realize a third photo-device layer 350. Here, in another embodiment, the p-type and n-type semiconductor layers may be switched, and the n-type and p-type semiconductor layers are selected in each layer depending on the type of the common electrode (n-type or p-type).

As described above, the photo-device layer may include a plurality of photo-device layers, and this improves the uniformity of color distribution and color reproduction upon color mixing or repeated formation of the active layer of the photo-device portion with low luminous efficacy as needed.

Therefore, the photo-device layers formed according to one embodiment of the present invention have buffer layers 210 and 310 interposed therebetween, the first type semiconductor layers 120, 220, and 320 may serve as n-type semiconductor layers or p-type semiconductor layers for the active layers 130, 230, and 330, and thus supply electrons or holes to the active layers 130, 230, and 330, and also may formed as high-concentration n-type semiconductor layers or p-type semiconductor layers and thus serve as electrode layers. In particular, according to one embodiment of the present invention, the n-type semiconductor layer, which is the first type semiconductor layer formed under the active layer 130, 230, 330, serves as an n-type electrode layer.

Each of these photo-device layers includes a first type semiconductor layer and a second type semiconductor layer, the photo-device portion with an appropriate structure and the electrode with an appropriate structure are appropriately formed and arranged, so that the overall device structure can be compact and a micro- or nano-light-emitting diode suitable for large-area, high-resolution displays can be manufactured.

In addition, the second type semiconductor layers 140, 240, and 340 are exposed to the top of the photo-device layers, and the first type semiconductor layers 120, 220, and 320 are opened on the bottom of the photo-device layers, so that photo-device portions having different emission wavelengths are formed in a horizontal direction based on the substrate 10 (FIGS. 1B, 1C, 1D, and 1E). More specifically, the first photo-device portion 410, the second photo-device portion 420, and the third photo-device portion 430 having different emission wavelengths are formed horizontally on the substrate 10 by sequentially opening parts of the semiconductor layers.

First, in order to form the third photo-device portion 430, a part of the second type semiconductor layer 340 of the third photo-device layer 350 is exposed, and the first type semiconductor layer 320 of the third photo-device layer 350 is opened to form the third photo-device portion 430 including the second type semiconductor layer 340, the third active layer 330 having a red emission wavelength, and the first type semiconductor layer 320 (FIGS. 1B and 1C). At this time, the third photo-device portion 430 is formed by masking an area of the third photo-device portion and etching the remaining area such that a part of the first type semiconductor layer 320 is opened. The open area of the first type semiconductor layer can be controlled by controlling the masking area as needed. In addition, a structurally stable third photo-device portion 430 may be formed by etching the buffer layer 310 below the opened first type semiconductor layer 320 and a part of the second type semiconductor layer 240 of the second photo-device layer 250 to open a part of the second type semiconductor layer 240 of the second photo-device layer 250.

In addition, after the second type semiconductor layer 240 of the second photo-device layer 250 is opened, a part of the second type semiconductor layer 240 of the second photo-device layer 250 is exposed, a part of the first type semiconductor layer 220 of the second photo-device layer 250 is opened to form a second photo-device portion 420 including the second type semiconductor layer 240, the second active layer 230 having a green emission wavelength, and the first type semiconductor layer 220 (FIGS. 1D and 1E). The second photo-device portion 420 is formed by masking areas of the third photo-device portion and the second photo-device portion, and etching the remaining area such that a part of the first type semiconductor layer 220 is opened. The open area of the first type semiconductor layer can be controlled by controlling the masking area as needed. In addition, a structurally stable second photo-device portion 420 may be formed by etching the buffer layer 210 below the opened first type semiconductor layer 220 and a part of the second type semiconductor layer 140 of the first photo-device layer 150 to open the part of the second type semiconductor layer 140 of the first photo-device layer 150.

In addition, after the second type semiconductor layer 140 of the first photo-device layer 150 is opened, a part of the second type semiconductor layer 140 of the first photo-device layer 150 is exposed, and the first type semiconductor layer 120 of the first photo-device layer 150 is opened to form a first photo-device portion 410 including the second type semiconductor layer 140, the first active layer 130 having a blue emission wavelength, and the first type semiconductor layer 120 (FIG. 1F). The first photo-device portion 410 is formed by masking areas of the third photo-device portion, the second photo-device portion and the first photo-device portion and etching the remaining area such that a part of the first type semiconductor layer 120 is opened. The open area of the first type semiconductor layer can be controlled by controlling the masking area as needed.

Here, the number of photo-device portions can be controlled in the horizontal direction by controlling the masking area and the open area of each semiconductor layer as needed. That is, combinations of RRGB, RRGGB, and RGGB as needed enable light emission, and the photo-device portions with low light emission efficiency are reinforced depending on the heights or positions of the materials or the devices to ensure uniformity of color distribution and color reproduction.

At this time, the first photo-device portion 410, the second photo-device portion 420, and the third photo-device portion 430 may be completely separated except for the substrate 10, and this can be realized by an isolation process, or the like. This allows each photo-device portion to operate independently and the photo-device portions are formed in the horizontal direction on the substrate 10, so that RGB pixels can be implemented by independent operation without color mixing between the photo-device portions.

In addition, the second optical device portion 420 and the third optical device portion 430 formed horizontally on the substrate 10 may horizontally share the first type semiconductor layer 220 and thus may be formed to operate independently or in conjunction with each other. A variety of photo-device portions that simultaneously emit light, such as RG, RGB, and GB, may be formed as needed.

In addition, a current spreading layer 510 may be optionally formed on each photo-device portion or an activation process may be optionally performed to further increase luminous efficacy (FIG. 1G). The activation process may be performed by heat treatment in a range of 200° C. to 900° C. for 30 seconds to 2 hours, and may be performed in an atmosphere of at least one of air, O₂, N₂, and Ar, or under vacuum. In addition, before forming the current spreading layer 510, the heat treatment may be performed at 200° C. to 900° C. for 30 seconds to 2 hours, and the activation process may be performed in an atmosphere of at least one of air, O₂, N₂, and Ar, or under vacuum, the current spreading layer 510 may be formed, and the heat treatment process may be repeated.

In addition, a first electrode 610 is formed in an area of the opened first type semiconductor layer 120, 220, or 320, and a second electrode 620 is formed on each photo-device portion (FIG. 1H).

In addition, the first electrode 610 is formed in a controlled open area of the first type semiconductor layers 220 and 320 so that each of the first type semiconductor layers 220 and 320 can serve as the first electrode 610 (e.g., n electrode) of the third photo-device portion 430 and the second photo-device portion 420. Here, the first type semiconductor layers 220 and 320 connected to the first electrode 610 may be formed as highly doped n⁺⁺ semiconductor layers (e.g., n⁺⁺-GaN layer) and may serve as electrode layers. In addition, the first type semiconductor layer 120 of the first photo-device portion 410 may also be doped at a high concentration to form a first electrode 610 serving as an electrode layer.

According to one embodiment of the present invention, the first type semiconductor layers 120, 220 and 320 supply electrons under the active layers 130, 230, and 330 as described above, and also serve as electrode layers of the photo-device portions when are doped at a high concentration to form first electrodes 610 in open areas.

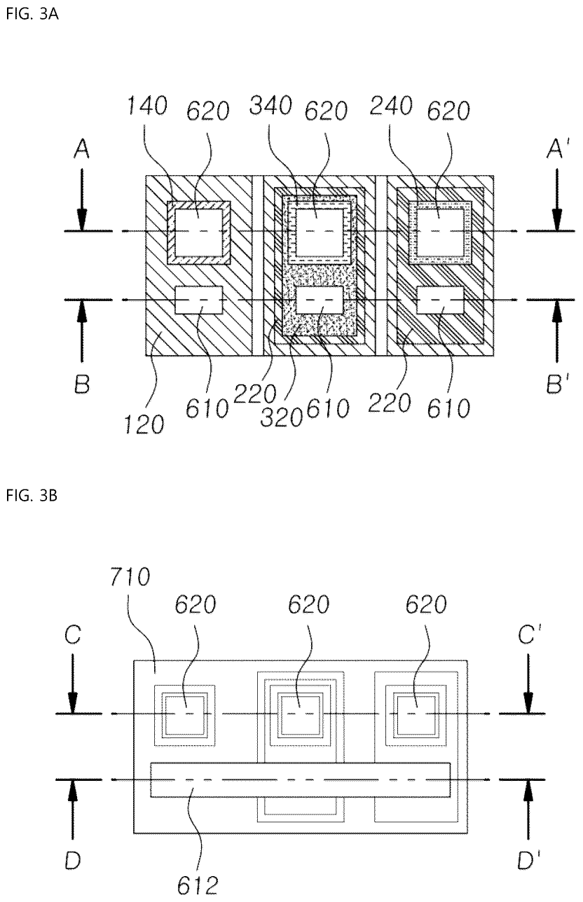

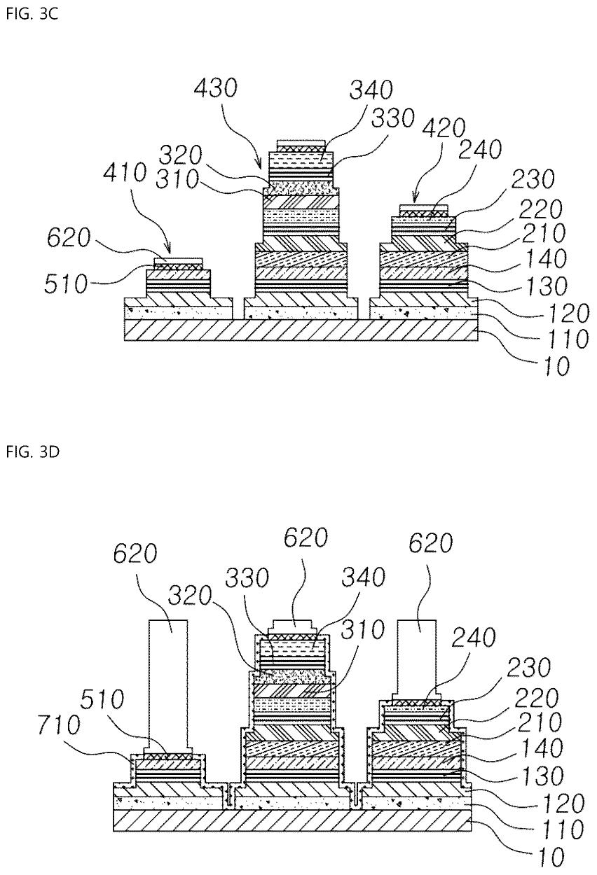

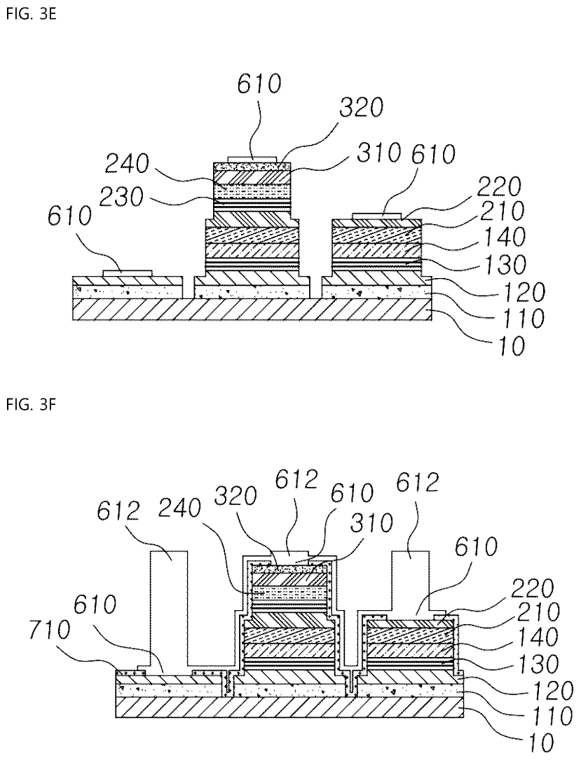

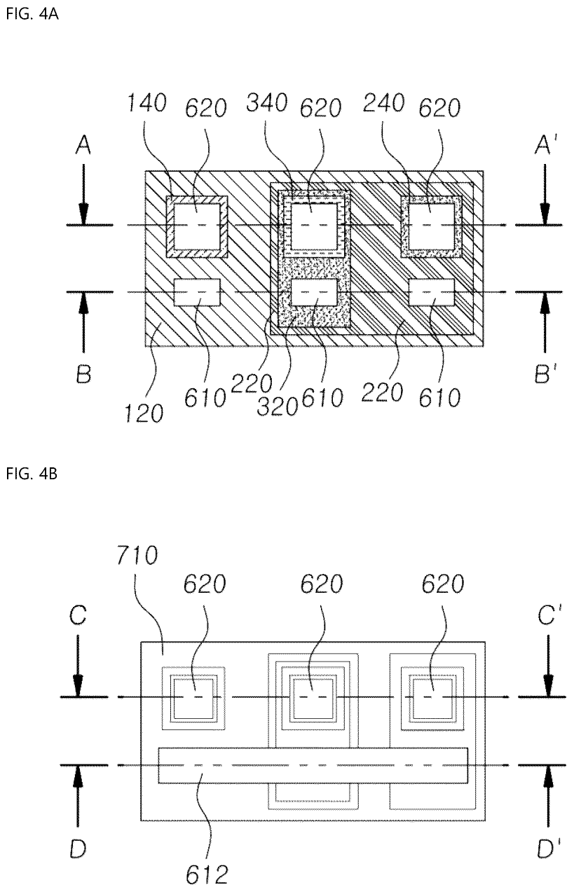

In addition, the first type semiconductor layers 120, 220, and 320 may be formed in any one open shape of a polygon (see FIGS. 3A, 3B, 3C, 3D, 3E, 3F, 4A, 4B, 4C, 4D, 4E, 4F, 5A, 5B, 5C, 5D and 6A, 6B, 6C, 6D, 6E and 6F), a bridge (see FIGS. 2A, 2B, 2C, 2D, 2E and 2F), a circle, and an ellipse, a second electrode 620 may be formed in each photo-device portion, and a first electrode 610 may be formed in the open area to realize the photo-device portion.

Here, the first electrodes 610 formed on the first type semiconductor layers 120, 220, and 320 of the photo-device portions are arranged in the same line and may be connected to each other to form a common electrode.

In addition, the first electrode 610 may be formed in any one of the polygonal, circular, elliptical, and bridge shapes, depending on the shape and structure of the photo-device portion, and the ends of the first electrodes 610 may be designed to be arranged on the same line to form a common electrode.

In addition, after the formation of the first electrode 610 and the second electrode 620, a passivation film 710 that opens the electrode area may be formed over the entire photoelectronic device, or a passivation film 710 may be first formed over the entire photoelectronic device, a part of the passivation film 710 may be opened, and the first electrode 610 and the second electrode 620 may be formed in the opened area (FIG. 1I).

Here, the passivation film 710 is formed to a thickness of 25 nm to 2 μm using at least one material of SiO₂, SiOₓ, SiNₓ, Si₃N₄, Al₂O₃, AlN, BN, TaN, TiN, ZrN, WN, VN, NbN, YN, or HfN.

After the formation of the passivation film 710, the first electrode 610, and the second electrode 620, the first electrodes 610 formed on the first type semiconductor layers 120, 220, and 320 may be connected to each other to form a common electrode (FIG. 1J). As described above, the first electrode 610 may be designed in a bridge shape to provide easy connection to the common electrode.

In addition, the first electrode 610 and the second electrode 620 may be formed to be flush with each other by adjusting the heights of the first electrode 610 and the second electrode 620. This enables easy connection of the photoelectronic device to a PCB or CMOS backplane.

The present invention aims at realizing an optimal structure that improves the spatial arrangement efficiency of electrodes and further increases luminous efficacy by designing the shape and structure of photo-device portions and controlling open areas.

Hereinafter, various embodiments of the present invention will be described in more detail with reference to the attached drawings.

### First Embodiment

As shown in FIGS. 2A, 2B, 2C, 2D, 2E and 2F, according to a first embodiment of the present invention, a buffer layer 110 is formed on a substrate 10, and a first photo-device portion 410 for emitting blue light, a second photo-device portion 420 for emitting green light, and a third photo-device portion 430 for emitting red light are formed on the buffer layer 110 in a horizontal direction based on the substrate 10.

In the epitaxial structure of the buffer layer and the photo-device layer that are stacked in a vertical direction, an area of the third photo-device portion is masked and the remaining area is etched such that a part of the first type semiconductor layer 320 of the third photo-device layer 350 is opened, to form the third photo-device portion 430.

Then, the third photo-device portion area and the second photo-device portion area are masked, and the remaining area is etched, the first type semiconductor layer 320 of the third photo-device layer 350 is etched in a bridge shape, and the first type semiconductor layer 220 of the second photo-device layer 250 is opened, so that the second photo-device portion 420 is formed in the bridge of the first type semiconductor layer 320 of the third photo-device layer 350 that has been etched in the bridge shape.

Then, the third photo-device portion area, the second photo-device portion area and the first photo-device portion area are masked, the remaining area is etched, the first type semiconductor layer 220 of the second photo-device layer 250 is etched in a bridge shape, and the first type semiconductor layer 120 of the first photo-device layer 150 is opened, so that the first photo-device portion 410 is formed in the bridge of the first type semiconductor layer 220 of the second photo-device layer 250 that has been etched in the bridge shape.

In this embodiment, a first electrode 610 is formed on each photo-device portion. In this case, the bridge of the first type semiconductor layer 220 of the second photo-device portion 420 and the bridge of the first type semiconductor layer 320 of the third photo-device portion 430 extend horizontally on the substrate 10, and the first electrode 610 is formed on the first type semiconductor layer 120 of the first photo-device portion 410 that is open between one side of each bridge and the bridge. As a result, the first electrode 610 is arranged on the same line on one side of the photoelectronic device, thus enabling easy formation of the common electrode and efficient spatial arrangement of the electrodes.

The common electrode is preferably formed over the entire area of the photoelectronic device after the passivation film 710 that opens an electrode area is formed. In addition, in some cases, before formation of the electrode, the passivation film 710 may be formed and the electrode may be formed in the open electrode area and then may be connected to the common electrode.

FIG. 2A is a planar schematic diagram illustrating the shape and structure of each photo-device portion and the arrangement of electrodes, and illustrates the configuration in which the first electrode 610 is formed in each photo-device portion, the first electrode 610 is formed on the bridge of the first type semiconductor layer 320 of the third photo-device portion 430, the first electrode 610 is formed on the bridge of the first type semiconductor layer 220 of the second photo-device portion 420, and the first electrode 610 is formed on the first type semiconductor layer 120 of the first photo-device portion 410. FIG. 2C is a cross-sectional schematic diagram taken along the line A-A′ of FIG. 2A, and FIG. 2E is a cross-sectional schematic diagram taken along the line B-B′ of FIG. 2A.

FIG. 2B is a planar schematic diagram illustrating the formation of the passivation film 710 and a common electrode for the first electrode 610, FIG. 2D is a cross-sectional schematic diagram taken along the line C-C′, and FIG. 2F is a cross-sectional schematic diagram taken along the line D-D′.

As such, the third photo-device portion 430 and the second photo-device portion 420 are formed such that the photo-device portions are horizontally arranged on the substrate 10 and the third photo-device portion 430 and the second photo-device portion 420 partially share the first type semiconductor layer of the second photo-device portion 420 in a horizontal direction, thereby providing a photoelectronic device that has a compact structure due to easy formation of a common electrode, minimizes color mixing problems, and exhibits excellent electrical characteristics due to reduced problems of high driving voltage and current leakage.

In addition, the first type semiconductor layers 320 and 220 are formed in a bridge shape and the first electrode 610 is arranged on one side such that the first electrode 610 can be easily connected to the common electrode, thereby improving the efficiency of the spatial arrangement of the electrodes, and enabling miniaturization of RGB pixels and application to large-area, high-resolution full-color displays.

### Second Embodiment

As shown in FIGS. 3A, 3B, 3C, 3D, 3E and 3F, according to the second embodiment of the present invention, a buffer layer 110 is formed on a substrate 10, and a first photo-device portion 410 for emitting blue light, a second photo-device portion 420 for emitting green light, and a third photo-device portion 430 for emitting red light are formed on the buffer layer 110 in a horizontal direction based on the substrate 10. Similar to the first embodiment, each photo-device portion is formed in an open area determined by masking and etching. In particular, in this embodiment, each photo-device portion can be completely isolated except for the substrate 10 and this configuration can be formed by an isolation process, or the like.

In this embodiment, the open areas of the first type semiconductor layers 320 and 220 of the third photo-device portion 430 and the second photo-device portion 420 are formed in a square shape. As a result, the open area of the first type semiconductor layer 120 of the first photo-device portion 410 is also formed in a square shape. In this embodiment, the open areas of the first type semiconductor layers 120, 220 and 320 form a square shape extending in a direction vertical to the arrangement direction of the photo-device portions.

By forming the first electrode 610 on each photo-device portion and forming the first electrode 610 in the extended areas on the first type semiconductor layers 120, 220, and 320 that are opened in the square shape, the first electrode 610 is arranged on one side of the RGB pixel, the formation of the common electrode is easy and the spatial arrangement of the electrodes is efficiently performed.

FIG. 3A is a planar schematic diagram illustrating the shape and structure of each photo-device portion and the arrangement of electrodes, and illustrates the configuration in which the first electrode 610 is formed in each photo-device portion, the first electrode 610 is formed on the first type semiconductor layer 320 of the third photo-device portion 430, the first electrode 610 is formed on the first type semiconductor layer 220 of the second photo-device portion 420, and the first electrode 610 is formed on the first type semiconductor layer 120 of the first photo-device portion 410. FIG. 3C is a cross-sectional schematic diagram taken along the line A-A′ of FIG. 3A, and FIG. 3E is a cross-sectional schematic diagram taken along the line B-B′ of FIG. 3A.

FIG. 3B is a planar schematic diagram illustrating the formation of the passivation film 710 and a common electrode for the first electrode 610, FIG. 3D is a cross-sectional schematic diagram taken along the line C-C′, and FIG. 3F is a cross-sectional schematic diagram taken along the line D-D′.

FIG. 3F illustrates a structure in which the first electrode 610 and the second electrode 620 are formed to be flush with each other by adjusting the heights of the first electrode 610 and the second electrode 620, thereby providing easy bonding with a PCB or CMOS backplane.

As such, the photo-device portions are horizontally arranged on the substrate 10, thereby providing a photoelectronic device that has a compact structure due to easy formation of a common electrode, minimizes color mixing problems, and exhibits excellent electrical characteristics due to reduced problems of high driving voltage and current leakage.

In addition, the photo-device portion is formed in a square shape and the first electrode 610 is arranged on one side thereof such that the first electrode 610 can be easily connected to the common electrode, thereby improving the efficiency of the spatial arrangement of the electrodes, and enabling miniaturization of RGB pixels and application to large-area, high-resolution full-color displays.

### Third Embodiment

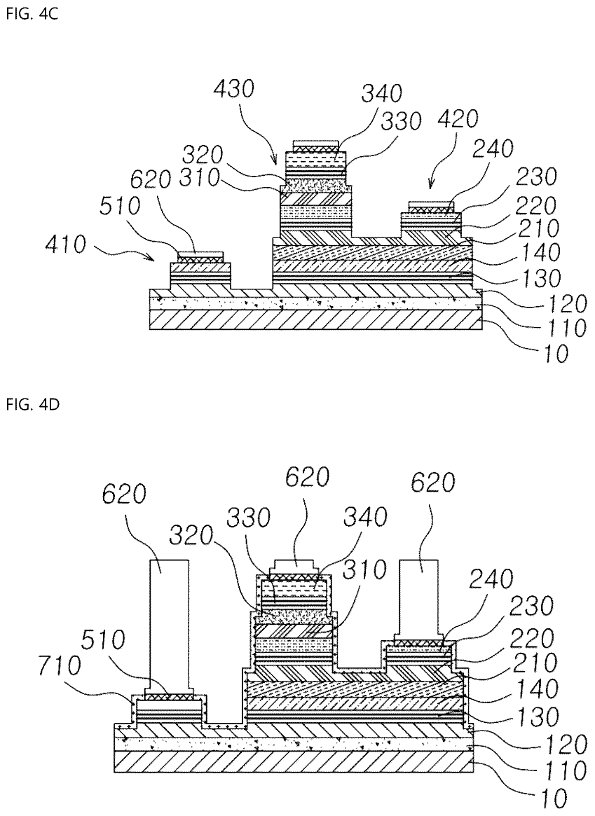

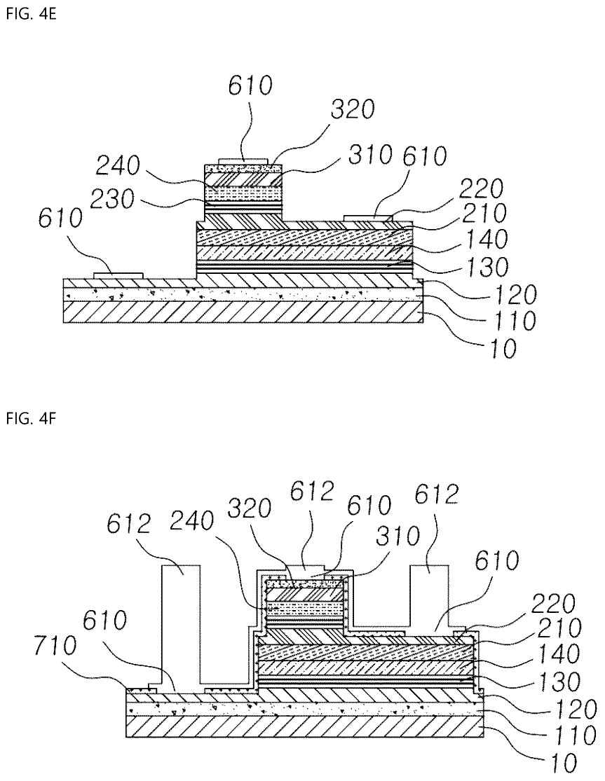

As shown in FIGS. 4A, 4B, 4C, 4D, 4E and 4F, according to a third embodiment of the present invention, a buffer layer 110 is formed on a substrate 10, and a first photo-device portion 410 for emitting blue light, a second photo-device portion 420 for emitting green light, and a third photo-device portion 430 for emitting red light are formed on the buffer layer 110 in a horizontal direction based on the substrate 10. Similar to the first embodiment and the second embodiment, each photo-device portion is formed in open and exposed areas determined by masking and etching.

In particular, in this embodiment, the second photo-device portion 420 and the third photo-device portion 430 horizontally share the first type semiconductor layer 220 of the second photo-device portion 420, and the open areas of the first type semiconductor layers 120, 220, and 320 form a square shape extending in a vertical direction to the arrangement direction of the photo-device portions.

In this embodiment, the open areas of the first type semiconductor layers 320 and 220 of the third photo-device portion 430 and the second photo-device portion 420 are formed in a square shape. As a result, the open area of the first type semiconductor layer 120 of the first photo-device portion 410 is also formed in a square shape.

By forming the first electrode 610 on each photo-device portion and forming the first electrode 610 on the first type semiconductor layer 120, 220, or 320 on an open area extending in a vertical direction to the arrangement direction of the photo-device portion, the first electrode 610 is arranged on one side of the RGB pixel, the formation of the common electrode is easy, and the spatial arrangement of the electrodes is efficiently performed.

FIG. 4A is a planar schematic diagram illustrating the shape and structure of each photo-device portion and the arrangement of electrodes, and illustrates the configuration in which the first electrode 610 is formed in each photo-device portion, the first electrode 610 is formed on the first type semiconductor layer 320 of the third photo-device portion 430, the first electrode 610 is formed on the first type semiconductor layer 220 of the second photo-device portion 420, and the first electrode 610 is formed on the first type semiconductor layer 120 of the first photo-device portion 410. FIG. 4C is a cross-sectional schematic diagram taken along line A-A′ of FIG. 4A, and FIG. 4E is a cross-sectional schematic diagram taken along line B-B′ of FIG. 4A.

FIG. 4B is a planar schematic diagram illustrating the formation of the passivation film 710 and a common electrode for the first electrode 610, FIG. 4D is a cross-sectional schematic diagram taken along line C-C′, and FIG. 4F is a cross-sectional schematic diagram taken along line D-D′.

FIG. 4F illustrates a structure in which the first electrode 610 and the second electrode 620 are formed to be flush with each other by adjusting the heights of the first electrode 610 and the second electrode 620, thereby providing easy bonding with a PCB or CMOS backplane.

As such, the third photo-device portion 430 and the second photo-device portion 420 are formed such that the photo-device portions are horizontally arranged on the substrate 10 and the third photo-device portion 430 and the second photo-device portion 420 horizontally share the first type semiconductor layer 220 of the second photo-device portion 420, thereby providing a photoelectronic device that has a compact structure due to easy formation of a common electrode, minimizes color mixing problems, and exhibits excellent electrical characteristics due to reduced problems of high driving voltage and current leakage.

In addition, the photo-device portion is formed in a square shape, and the first electrode 610 is arranged on one side thereof such that the first electrode 610 can be easily connected to the common electrode, thereby improving the efficiency of the spatial arrangement of the electrodes, and enabling miniaturization of RGB pixels and application to large-area, high-resolution full-color displays.

### Fourth Embodiment

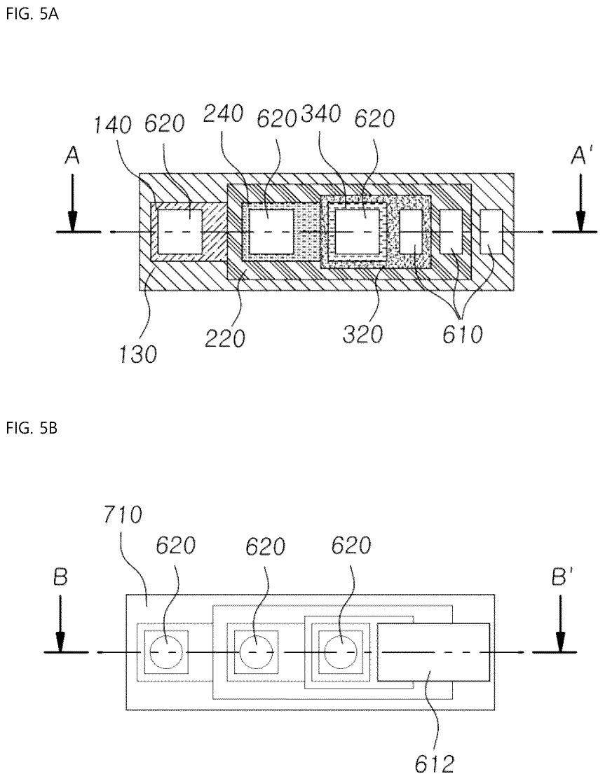

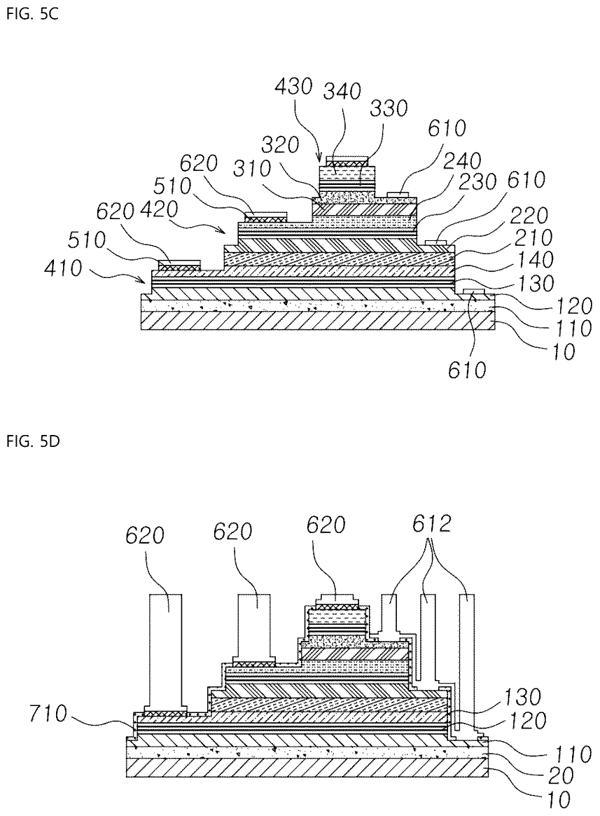

As shown in FIGS. 5A, 5B, 5C and 5D, according to a fourth embodiment of the present invention, a buffer layer is formed on a substrate 10, and a first photo-device portion 410 for emitting blue light, a second photo-device portion 420 for emitting green light, and a third photo-device portion 430 for emitting red light are formed on the buffer layer 110 in a horizontal direction based on the substrate 10. Similar to the first embodiment and the second embodiment, each photo-device portion is formed in open and exposed areas determined by masking and etching.

In particular, in this embodiment, the second photo-device portion 420 and the third photo-device portion 430 horizontally share the first type semiconductor layer 220 of the second photo-device portion 420, the second photo-device portion 420 and the third photo-device portion 430 horizontally share the first type semiconductor layer 120 with the first photo-device portion 410, and the first electrode 610 is formed on the first type semiconductor layer 120, 220, or 320 that is open parallel to the arrangement direction of the photo-device portion.

In this embodiment, the open areas of the first type semiconductor layers 320 and 220 of the third photo-device portion 430 and the second photo-device portion 420 are formed in a square shape. As a result, the open area of the first type semiconductor layer 120 of the first photo-device portion 410 is also formed in a square shape.

The first electrode 610 is formed on each photo-device portion, and the first electrode 610 is formed on the first type semiconductor layer 120, 220, or 320 that opens parallel to the arrangement direction of the photo-device portion.

FIG. 5A is a planar schematic diagram illustrating the shape and structure of each photo-device portion and the arrangement of electrodes, and illustrates the configuration in which the first electrode 610 is formed on each photo-device portion and the first electrode 610 is formed on the first type semiconductor layer 120, 220 or 320. FIG. 5C is a cross-sectional schematic diagram taken along line A-A′ of FIG. 5A.

FIG. 5B is a planar schematic diagram illustrating the formation of the passivation film 710 and the first electrode 610 as a common electrode, FIG. 5D is a cross-sectional schematic diagram taken along line B-B′ of FIG. 5B and illustrates a structure in which the first electrode 610 and the second electrode 620 are formed to be flush with each other by adjusting the heights of the first electrode 610 and the second electrode 620, thereby providing easy bonding with a PCB or CMOS backplane.

As such, the photo-device portions are horizontally arranged on the substrate 10, the third photo-device portion 430 and the second photo-device portion 420 horizontally share the first type semiconductor layer 220 of the second photo-device portion 420, and the third photo-device portion 430 and the first photo-device portion 410 horizontally share the first type semiconductor layer 120 of the first photo-device portion 410, thereby providing a photoelectronic device that has a compact structure due to easy formation of a common electrode, minimizes color mixing problems, and exhibits excellent electrical characteristics due to reduced problems of high driving voltage and current leakage.

In addition, the photo-device portion is formed in a square shape and the first electrode 610 is arranged on one side thereof such that the first electrode 610 can be easily connected to the common electrode, thereby improving the efficiency of the spatial arrangement of the electrodes, and enabling miniaturization of RGB pixels and application to large-area, high-resolution full-color displays.

In addition, in this embodiment, the second photo-device portion 420 and the third photo-device portion 430 horizontally share the first type semiconductor layer 220 of the second photo-device portion 420 and the first type semiconductor layer 120 of the first photo-device portion 410 such that the photo-device portions 420 may operate independently from or in conjunction with each other. As a result, the area of the photo-device portion that has low luminous efficacy or is located far from the luminous surface is increased, as needed, the photo-device portion with low luminous efficacy can be reinforced, and the uniformity of color distribution and color reproduction can thus be improved. For example, in the embodiment of the present invention, the area of the green light-emitting photo-device portion with low luminous efficacy is wide, thereby providing the effect of forming RGGB, RGBBB, and RGGBBB pixels.

That is, in the fourth embodiment, the photo-device portions share the first type semiconductor layers 120 and 220, and the active layers 130 and 230 horizontally with each other, so that the active layer region of the third photo-device portion 430 is limited to the third photo-device portion area and light emission occurs the third photo-device portion area, the active layer 230 of the second photo-device portion 420 extends to the third photo-device portion area and light emission occurs in the third photo-device portion area and the second photo-device portion area, and the active layer 130 of the first photo-device portion 410 extends to the second photo-device portion area and the third photo-device portion area and light emission occurs in all of the third photo-device portion area, the second photo-device portion area and the first photo-device portion area.

As such, the present invention has the advantage of easy expansion of the light-emitting region based on the structure in which the respective photo-device portions share some of the first type semiconductor layer and the active layer horizontally with each other.

### Fifth Embodiment

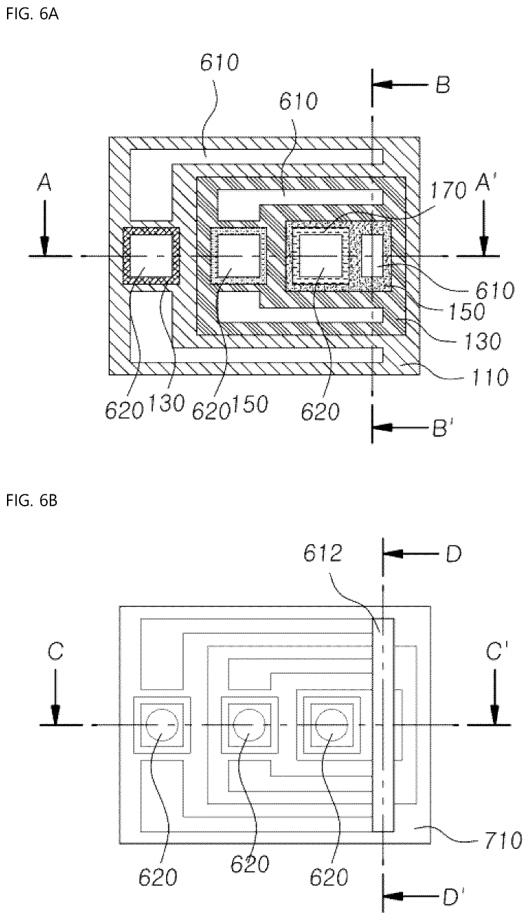

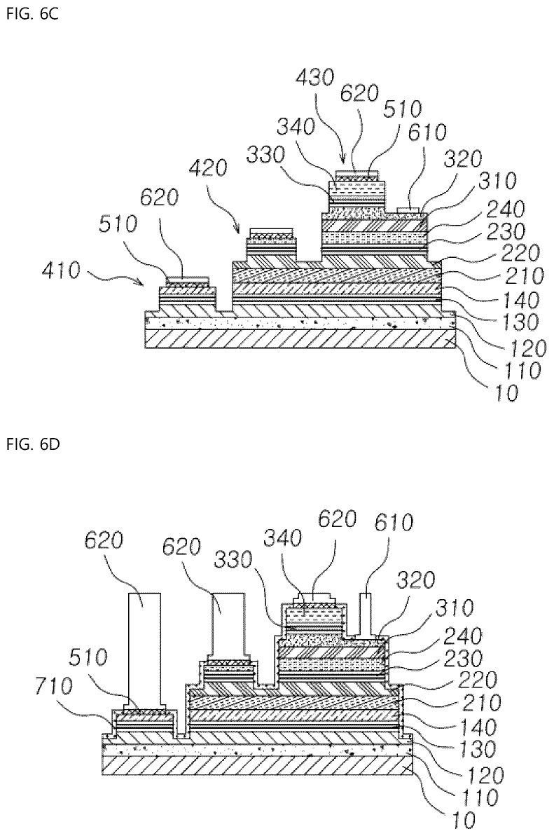

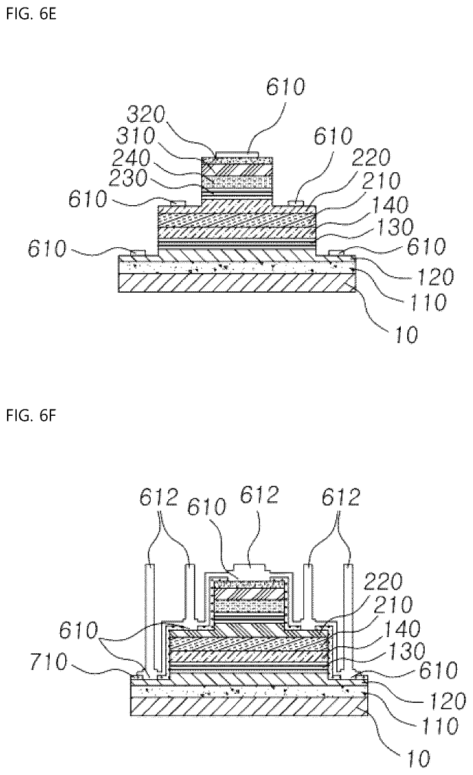

As shown in FIGS. 6A, 6B, 6C, 6D, 6E and 6F, according to a fifth embodiment of the present invention, a buffer layer 110 is formed on a substrate 10, and a first photo-device portion 410 for emitting blue light, a second photo-device portion 420 for emitting green light, and a third photo-device portion 430 for emitting red light are formed on the buffer layer 110 in a horizontal direction based on the substrate 10. Similar to the first embodiment and the second embodiment, each photo-device portion is formed in open and exposed areas determined by masking and etching.

In particular, in this embodiment, the second photo-device portion 420 and the third photo-device portion 430 horizontally share the first type semiconductor layer 220 of the second photo-device portion 420, the open area of the first type semiconductor layer 320 of the third photo-device portion 430 forms a square shape extending in a direction parallel to the arrangement direction of the photo-device portion and the open area of the first type semiconductor layer 220 of the second photo-device portion 420 form a square shape extending in a direction vertical to the arrangement direction of the photo-device portion.

In this embodiment, the open areas of the first type semiconductor layers 320 and 220 of the third photo-device portion 430 and the second photo-device portion 420 are formed in a square shape. As a result, the open area of the first type semiconductor layer 120 of the first photo-device portion 410 is also formed in a square shape.

The first electrode 610 is formed on each photo-device portion, the first electrode 610 is formed on the first type semiconductor layer 320 of the third photo-device portion 430 on an open area extending in a direction parallel to the arrangement direction of the photo-device portion, the first electrode 610 is formed in the form of a bridge on the first type semiconductor layer 220 of the second photo-device portion 420 on an open area extending to two sides of the photo-device portion in a direction vertical to the arrangement direction of the photo-device portion, and the first electrode 610 formed on the first type semiconductor layer 320 of the third photo-device portion 430 is also formed in a bridge shape toward the outside at a position adjacent to the first photo-device portion 410.

Therefore, one end of each of the first electrode 610 of the third photo-device portion 430, the bridge-type first electrode 610 of the second photo-device 420, and the bridge-type first electrode 610 of the first photo-device 410 is arranged on one side of the device and the common electrode is formed, thereby making the spatial arrangement of the electrodes efficient.

FIG. 6A is a planar schematic diagram illustrating the shape and structure of each photo-device portion and the arrangement of electrodes, and illustrates the configuration in which the second electrode 620 is formed in each photo-device portion, the first electrode 610 is formed on the first type semiconductor layer 320 of the third photo-device portion 430, the first electrode 610 is formed in the form of a bridge on the first type semiconductor layer 220 of the second photo-device portion 420, and the first electrode 610 is formed in the form of a bridge on the first type semiconductor layer 120 of the first photo-device portion 410.

FIG. 6C is a cross-sectional schematic diagram taken along line A-A′ of FIG. 6A and FIG. 6E is a cross-sectional schematic diagram taken along line B-B′ of FIG. 6A.

FIG. 6B is a planar schematic diagram illustrating the formation of the passivation film 710 and the common electrode for the first electrode 610, FIG. 6D is a cross-sectional schematic diagram taken along line C-C′, and FIG. 6F is a cross-sectional schematic diagram taken along line D-D′.

FIG. 6F illustrates a structure in which the first electrode 610 and the second electrode 620 are formed to be flush with each other by adjusting the heights of the first electrode 610 and the second electrode 620, thereby providing easy bonding with a PCB or CMOS backplane.

As such, the photo-device portions are horizontally arranged on the substrate 10 and the third photo-device portion 430 and the second photo-device portion 420 horizontally share the first type semiconductor layer 220 of the second photo-device portion 420, thereby providing a photoelectronic device that has a compact structure due to easy formation of a common electrode, minimizes color mixing problems, and exhibits excellent electrical characteristics due to reduced problems of high driving voltage and current leakage.

In addition, the photo-device portion is formed in a square shape, and the first electrode 610 is arranged in the form of a bridge and square on one side thereof such that the first electrode 610 can be easily connected to the common electrode, thereby improving the efficiency of the spatial arrangement of the electrodes, and enabling miniaturization of RGB pixels and application to large-area, high-resolution full-color displays.

In addition, by forming a bridge-type first electrode 610, the area of the electrode is increased, the spreading effect of carriers (e.g., electrons) is improved, and the luminous efficacy can be further improved.

As such, the photoelectronic device according to the embodiment of the present invention aims at realizing an optimal structure that improves the spatial arrangement efficiency of electrodes and further increases the luminous efficacy by designing the shape and structure of photo-device portions and controlling open areas.

In addition, according to the present invention, in an epi structure in which a plurality of photo-device layers including a first type semiconductor layer, an active layer, and a second type semiconductor layer are formed vertically, and a buffer layer is formed between the photo-device layers, photo-device portions are arranged horizontally on a substrate through selective etching and opening processes, so that a full-color RGB pixel that exhibits excellent reproducibility over a large area and can be mass-produced can be realized.

In addition, by forming the photo-device portion such that the photo-device portion shares a part of the first type semiconductor layer of the photo-device layer formed in the middle, it is possible to provide a photoelectronic device that has a compact structure due to easy formation of a common electrode, minimizes color mixing problems because RGB pixels can be implemented in a horizontal direction on a single substrate, and exhibits excellent electrical characteristics due to reduced problems of high driving voltage and current leakage.

In addition, the photoelectronic device according to one embodiment of the present invention has a structure in which the first electrodes 610 are connected to each other to form a common electrode, or exhibits improved spreading effect of electrons and thus improved luminous efficacy because the area of the first electrode can be adjusted.

In addition, based on the selective sharing structure of some of the first type semiconductor layers in the photo-device portions, the photo-device portions can operate independently from or in conjunction with each other, and can easily operate one or more photo-device portions depending on the emission wavelength as needed, so that the light-emitting area can be easily controlled, the photo-device portion with low light-emitting efficiency can be reinforced and the uniformity of color distribution and color reproduction can be improved.

In addition, based on the structure in which the photo-device portions horizontally share some of the first type semiconductor layers and the active layers with each other, the light-emitting area of each photo-device portion can be easily increased.

As apparent from the foregoing, according to the present invention, in an epi structure in which a plurality of photo-device layers including a first type semiconductor layer, an active layer, and a second type semiconductor layer are formed vertically, and a buffer layer is formed between the photo-device layers, photo-device portions are arranged horizontally on a substrate through selective etching and opening processes, so that a full-color RGB pixel that exhibits excellent reproducibility over a large area and can be mass-produced can be realized.

In addition, by forming the photo-device portion such that the photo-device portion shares a part of the first type semiconductor layer of the photo-device layer formed in the middle, it is possible to provide a photoelectronic device that has a compact structure due to easy formation of a common electrode, minimizes color mixing problems because RGB pixels can be implemented in a horizontal direction on a single substrate, and exhibits excellent electrical characteristics due to reduced problems of high driving voltage and current leakage.

In addition, the photoelectronic device according to one embodiment of the present invention has a structure in which the first electrodes 610 are connected to each other to form a common electrode, or exhibits improved spreading effect of electrons and thus improved luminous efficacy because the area of the first electrode can be adjusted.

In addition, based on the selective sharing structure of some of the first type semiconductor layers in the photo-device portions, the photo-device portions can operate independently from or in conjunction with each other, and can easily operate one or more photo-device portions depending on the emission wavelength as needed, so that the light-emitting area can be easily controlled, the photo-device portion with low light-emitting efficiency can be reinforced and the uniformity of color distribution and color reproduction can be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a photoelectronic device having multiple wavelengths, the method comprising:
forming a plurality of photo-device layers having different emission wavelengths on a substrate, each photo-device layer comprising a first type semiconductor layer, an active layer, and a second type semiconductor layer from the substrate;
forming a buffer layer between the photo-device layers;
exposing the second type semiconductor layer to top of each photo-device layer, and opening the first type semiconductor layer on the bottom of each photo-device layer to form a plurality of photo-device portions having different emission wavelengths in a horizontal direction based on the substrate;
forming a first electrode in one region on the opened first type semiconductor layer; and
forming a second electrode on each photo-device portion.

2. The method according to claim 1, wherein the photo-device portions operate independently from one another.

3. The method according to claim 1, wherein the photo-device portions horizontally share at least one of the first type semiconductor layers and operate independently from or in conjunction with one another.

4. The method according to claim 1, wherein an open area of the first type semiconductor layer has one shape of a polygon, a circle, an ellipse, or a bridge.

5. The method according to claim 4, wherein the first electrodes formed on the first type semiconductor layers are arranged on the same horizontal line and are connected to each other to form a common electrode.

6. The method according to claim 1, further comprising forming a passivation film opening an electrode area over the entire area of the photoelectronic device before or after forming the first electrode and the second electrode.

7. The method according to claim 6, further comprising connecting the first electrodes formed on the first type semiconductor layer to each other to form a common electrode after forming the passivation film.

8. The method according to claim 1, wherein the first electrode and the second electrode are formed to be flush with each other by adjusting the heights of the first electrode and the second electrode.

9. The method according to claim 1, wherein the substrate comprises silicon (Si), gallium arsenide (GaAs), gallium phosphide (GaP), gallium arsenide phosphide (GaAsP), boron nitride (BN), SiC, GaN, ZnO, MgO, InP, Ge, InAs, GaSb, sapphire, quartz, or glass.

10. The method according to claim 1, further comprising forming a buffer layer between the substrate and the lowermost first type semiconductor layer.

11. The method according to claim 10, wherein the buffer layer is a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or comprises a plurality of layers including a combination of two or more layers, or is a single layer containing two or more materials thereof or comprises a plurality of layers including a combination of two or more layers.

12. The method according to claim 1, wherein the first type semiconductor layer is an n-type semiconductor layer or a p-type semiconductor layer, and the second type semiconductor layer is a p-type semiconductor layer or an n-type semiconductor layer.

13. The method according to claim 12, wherein the n-type semiconductor layer is a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or comprises a plurality of layers including a combination of two or more layers, or is a single layer containing two or more materials thereof or comprises a plurality of layers including a combination of two or more layers, and
the p-type semiconductor layer is a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or comprises a plurality of layers including a combination of two or more layers, or is a single layer containing two or more materials thereof or comprises a plurality of layers including a combination of two or more layers.

14. The method according to claim 1, wherein the active layer is formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb.

15. The method according to claim 1, wherein the first type semiconductor layer or the second type semiconductor layer is any one layer, a plurality of layers or a p/n junction layer of an n⁺⁺-GaN layer, a p⁺⁺-GaN layer, an n⁺⁺-InGaN layer, a p⁺⁺-InGaN layer, an n⁺⁺-AlGaN layer, a p⁺⁺-AlGaN layer, an n⁺⁺-GaAs layer, a p⁺⁺-GaAs layer, an n⁺⁺-InGaAs layer, a p⁺⁺-InGaAs layer, an n⁺⁺-AlGaAs layer, or a p⁺⁺-AlGaAs.

16. The method according to claim 1, wherein, when the first type semiconductor layer is formed as a p-type semiconductor layer, or when the second type semiconductor layer is formed as a p-type semiconductor layer, a diffusion prevention layer or an electron blocking layer is formed between each active layer and the p-type semiconductor layer.

17. The method according to claim 1, wherein the first electrode is formed in any one shape of a polygon, a circle, an ellipse, or a bridge.

18. The method according to claim 17, wherein the first electrodes are arranged on the same horizontal line and are connected to each other to form a common electrode.

19. A photoelectronic device having multiple wavelengths, comprising:
a plurality of photo-device layers having different emission wavelengths formed on a substrate, each photo-device layer comprising a first type semiconductor layer, an active layer, and a second type semiconductor layer from the substrate;
a buffer layer formed between the photo-device layers;
a plurality of photo-device portions having different emission wavelengths formed in a horizontal direction based on the substrate such that the second type semiconductor layer is exposed to a top of each photo-device layer and the first type semiconductor layer is opened on a bottom of each photo-device layer;
a first electrode formed in one region on the opened first type semiconductor layer; and
a second electrode formed on each photo-device portion.

20. The photoelectronic device according to claim 19, wherein the photo-device portions operate independently from one another.

21. The photoelectronic device according to claim 19, wherein the photo-device portions horizontally share at least one of the first type semiconductor layers and operate independently from or in conjunction with one another.

22. The photoelectronic device according to claim 19, wherein an open area of the first type semiconductor layer has one shape of a polygon, a circle, an ellipse, or a bridge.

23. The photoelectronic device according to claim 22, wherein the first electrodes formed on the first type semiconductor layers are arranged on the same horizontal line and are connected to each other to form a common electrode.

24. The photoelectronic device according to claim 19, further comprising forming a passivation film opening an electrode area over the entire area of the photoelectronic device before or after forming the first electrode and the second electrode.

25. The photoelectronic device according to claim 24, further comprising connecting the first electrodes formed on the first type semiconductor layer to each other to form a common electrode after forming the passivation film.

26. The photoelectronic device according to claim 19, wherein the first electrode and the second electrode are formed to be flush with each other by adjusting the heights of the first electrode and the second electrode.

27. The photoelectronic device according to claim 19, wherein the substrate comprises silicon (Si), gallium arsenide (GaAs), gallium phosphide (GaP), gallium arsenide phosphide (GaAsP), boron nitride (BN), SiC, GaN, ZnO, MgO, InP, Ge, InAs, GaSb, sapphire, quartz, or glass.

28. The photoelectronic device according to claim 19, further comprising forming a buffer layer between the substrate and the lowermost first type semiconductor layer.

29. The photoelectronic device according to claim 28, wherein the buffer layer is a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or comprises a plurality of layers including a combination of two or more layers, or is a single layer containing two or more materials thereof or comprises a plurality of layers including a combination of two or more layers.

30. The photoelectronic device according to claim 19, wherein the first type semiconductor layer is an n-type semiconductor layer or a p-type semiconductor layer, and the second type semiconductor layer is a p-type semiconductor layer or an n-type semiconductor layer.

31. The photoelectronic device according to claim 30, wherein the n-type semiconductor layer is a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or comprises a plurality of layers including a combination of two or more layers, or is a single layer containing two or more materials thereof or comprises a plurality of layers including a combination of two or more layers, and
the p-type semiconductor layer is a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or comprises a plurality of layers including a combination of two or more layers, or is a single layer containing two or more materials thereof or comprises a plurality of layers including a combination of two or more layers.

32. The photoelectronic device according to claim 19, wherein the active layer is formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb.

33. The photoelectronic device according to claim 19, wherein the first type semiconductor layer or the second type semiconductor layer is any one layer, a plurality of layers or a p/n junction layer of an n⁺⁺-GaN layer, a p⁺⁺-GaN layer, an n⁺⁺-InGaN layer, a p⁺⁺-InGaN layer, an n⁺⁺-AlGaN layer, a p⁺⁺-AlGaN layer, an n⁺⁺-GaAs layer, a p⁺⁺-GaAs layer, an n⁺⁺-InGaAs layer, a p⁺⁺-InGaAs layer, an n⁺⁺-AlGaAs layer, or a p⁺⁺-AlGaAs.

34. The photoelectronic device according to claim 19, wherein, when the first type semiconductor layer is formed as a p-type semiconductor layer, or when the second type semiconductor layer is formed as a p-type semiconductor layer, a diffusion prevention layer or an electron blocking layer is formed between each active layer and the p-type semiconductor layer.

35. The photoelectronic device according to claim 19, wherein the first electrode is formed in any one shape of a polygon, a circle, an ellipse, or a bridge.

36. The photoelectronic device according to claim 35, wherein the first electrodes are arranged on the same horizontal line and are connected to each other to form a common electrode.
